(19) United States
(12) Patent Application Publication
(10) Pub. No.: US 2024/0306382 A1
(43) Pub. Date: Sep. 12, 2024

(54) SEMICONDUCTOR DEVICE AND METHOD OF MANUFACTURING THE SAME

(71) Applicant: Renesas Electronics Corporation, Tokyo (JP)

(72) Inventors: Eiji HIRAIWA, Tokyo (JP); Taisei NAGAI, Tokyo (JP); Shu SHIMIZU, Tokyo (JP); Takeshi NAKURA, Tokyo (JP)

(21) Appl. No.: 18/436,731

(22) Filed: Feb. 8, 2024

(30) Foreign Application Priority Data
Mar. 9, 2023 (JP) 2023-036797

(51) Int. Cl. H10B 20/00; H01L 21/02; H01L 21/762; H01L 23/525

(52) U.S. Cl. CPC H10B 20/30; H01L 21/02595; H01L 21/762; H01L 23/5252

(57) ABSTRACT

A semiconductor device includes a fuse transistor in an active region. In a first direction, the active region is defined by first and second element isolation films. The fuse transistor includes a gate dielectric film, a gate electrode, and semiconductor regions on both sides of the gate electrode in a second direction perpendicular to the first direction. In the first direction, the gate dielectric film has a central portion, a first peripheral portion and a second peripheral portion. The central portion is spaced apart from the first element isolation film and the second element isolation film, the first peripheral portion reaches the first element isolation film, and the second peripheral portion reaches the second element isolation film. The central portion of the gate dielectric film has a first thickness, and each of the first peripheral portion and the second peripheral portion has a second thickness greater than the first thickness.

### CROSS-REFERENCE TO RELATED APPLICATIONS

The disclosure of Japanese Patent Application No. 2023-036797 filed on Mar. 9, 2023, including the specification, drawings and abstract is incorporated herein by reference in its entirety.

### BACKGROUND

The present disclosure relates to a semiconductor device and method of manufacturing the same, and can be suitably used, for example, in a semiconductor device including an antifuse element and a method of manufacturing the same.

As a semiconductor device including a memory formed of a semiconductor element formed on a semiconductor substrate, there is a semiconductor device including a memory cell including an antifuse element. In this semiconductor device, a high voltage is applied between the gate electrode of the antifuse element and the source region and the drain region to cause the gate dielectric film of the antifuse element to break down, whereby data is written to the memory cell. In the antifuse element in which the gate dielectric film is broken down, the gate leakage current is increased. Therefore, information (“0” or “1”) can be determined by applying a read voltage to the gate electrode and measuring the read current between the gate electrode and the source region and the drain region. That is, a memory cell indicating a sufficient read current value (equal to or greater than the determination reference value) is determined as, for example, information “1”.

There are disclosed techniques listed below.
[Patent Document 1] Japanese Unexamined Patent Application Publication No. 2011-119640

In addition, since the breakdown of the gate dielectric film in the antifuse element is only once, the writing of the memory cell is referred to as OTP (One Time Program). Further, the memory element including an antifuse element is referred to as an OTP memory element, and is used for ROM (Read Only Memory). Patent Document 1 discloses an antifuse element, for example.

### SUMMARY

The inventors of the present application have confirmed the following problems in a semiconductor device including a memory cell including an antifuse element (hereinafter referred to as a fuse transistor) having a MOS structure.

The semiconductor device is built into the chip. In a manufacturing step of the semiconductor device, a semiconductor wafer (for example, a 300 mm diameter disk) in which a large number of semiconductor chips are disposed in a matrix is used. The manufacturing step includes steps such as photolithography, deposition of a conductive film and a dielectric film, etching, and polishing (CMP (Chemical Mechanical Polishing)). In each manufacturing step, all the semiconductor chips in the semiconductor wafer cannot be processed with the same processing accuracy, and processing variation called “in-plane variation” occur in the semiconductor wafer. The “in-plane variation” is a processing variation caused by a difference in the arrangement positions of the semiconductor chips. For example, a finished dimensional error with respect to a design value occurs between a semiconductor chip disposed in a central portion of a semiconductor wafer and a semiconductor chip disposed in a peripheral portion.

The inventors of the present application have confirmed that a memory cell indicating an insufficient read current (referred to as “defective bit”) occurs in a semiconductor device including a memory cell including a fuse transistor. Then, the inventors have confirmed that the cause of the generation of the defective bit was caused by the “in-plane variation” in the manufacturing step of semiconductor device. In a the semiconductor device including a memory cell including a fuse transistor, an improvement in a read current of the memory cell is required. Other objects and novel features will become apparent from the description of this specification and the accompanying drawings.

In one embodiment, a semiconductor device includes a semiconductor substrate having a main surface, and a first element isolation film and a second element isolation film disposed to sandwich a portion of the semiconductor substrate in a first direction along the main surface so as to define a first active region and extending from the main surface toward an inside of the semiconductor substrate, respectively. In plan view, the semiconductor device includes a first transistor formed in the first active region. The first transistor includes a first gate dielectric film formed on the main surface of the semiconductor substrate and a first gate electrode formed on the first gate dielectric film. The first transistor further includes a first semiconductor region and a second semiconductor region located on both sides of the first gate electrode in a second direction perpendicular to the first direction and formed in the semiconductor substrate. In the first direction, the first gate dielectric film includes a first portion disposed spaced apart from the first element isolation film and the second element isolation film, a second portion disposed between the first portion and the first element isolation film, and the third portion disposed between the first portion and the second element isolation film. The second portion of the first gate dielectric film reaches the first element isolation film, and third portion of the first element isolation film reaches the second element isolation film. Further, the first portion of the first gate dielectric film has a first thickness, and each of the second portion and the third portion of the first gate dielectric film has a second thickness, the second thickness is greater than the first thickness.

In one embodiment, a manufacturing method of a semiconductor device includes: preparing a semiconductor substrate having a main surface; and forming a first element isolation film and a second element isolation film extending from the main surface toward the inside of semiconductor substrate and disposed to sandwich one region of the main surface of the semiconductor substrate in a first direction along the main surface so as to define a first active region, respectively. The manufacturing method of the semiconductor device further includes forming a first gate dielectric film on the main surface of the semiconductor substrate and forming a first gate electrode on the first gate dielectric film in the first active region. The manufacturing method of the semiconductor device further includes a first semiconductor region and a second semiconductor region on both sides of the first gate electrode in a second direction perpendicular to the first direction and in the semiconductor substrate in the first active region. The first gate dielectric film includes a first portion disposed spaced apart from the first element isolation film and the second element isolation film, a second portion disposed between the first portion and the first element isolation film, and a third portion disposed between the first portion and the second element isolation film. Then, the second portion of the gate dielectric film reaches the first element isolation film, and the third portion of the first element isolation film reaches the second element isolation film. And, the first portion of the first gate dielectric film has a first thickness, and each of the second portion and the third portion of the first gate dielectric film has a second thickness, and the second thickness is greater than the first thickness.

According to the embodiment, improving the read current can improve the reliability of semiconductor device.

### BRIEF DESCRIPTION OF THE DRAWINGS

FIG. 1 is a plan view of a transistor included in a semiconductor device in a present embodiment.

FIG. 2 is a cross-sectional view in a gate length direction of the transistor included in the semiconductor device in the present embodiment.

FIG. 3 a cross-sectional view in a gate width direction of the transistor included in the semiconductor device in the present embodiment.

FIG. 4 is an equivalent circuit diagram of a memory cell portion of the semiconductor device in the present embodiment.

FIG. 5 is a cross-sectional view showing the write mechanism of the fuse transistor in the present embodiment.

FIG. 6 is a cross-sectional view showing the write mechanism of the fuse transistor in the present embodiment.

FIG. 7 is a cross-sectional view showing a manufacturing step in a gate width direction of the transistor included in the semiconductor device in the present embodiment.

FIG. 8 is a cross-sectional view showing a manufacturing step in the gate width direction of the transistor included in the semiconductor device in the present embodiment subsequent to FIG. 7.

FIG. 9 is a cross-sectional view showing a manufacturing step in the gate width direction of the transistor included in the semiconductor device in the present embodiment subsequent to FIG. 8.

FIG. 10 is a cross-sectional view showing a manufacturing step in the gate width direction of the transistor included in the semiconductor device in the present embodiment subsequent to FIG. 9.

FIG. 11 is a cross-sectional view showing a manufacturing step in the gate width direction of the transistor included in the semiconductor device in the present embodiment subsequent to FIG. 10.

FIG. 12 is a cross-sectional view showing a manufacturing step in the gate width direction of the transistor included in the semiconductor device in the present embodiment subsequent to FIG. 11.

FIG. 13 is a plan view of the fuse transistor in the manufacturing step shown in FIG. 12.

FIG. 14 is a cross-sectional view showing a manufacturing step in the gate width direction of the transistor included in the semiconductor device in the present embodiment subsequent to FIG. 12.

FIG. 15 is a cross-sectional view showing a manufacturing step in the gate width direction of the transistor included in the semiconductor device in the present embodiment subsequent to FIG. 14.

FIG. 16 is a cross-sectional view showing a manufacturing step in the gate width direction of the transistor included in the semiconductor device in the present embodiment subsequent to FIG. 15.

FIG. 17 is a cross-sectional view of a fuse transistor in a gate width direction in a related art.

FIG. 18 is a main portion enlarged cross-sectional view showing a manufacturing step of the fuse transistor in the related art.

FIG. 19 is a main portion enlarged cross-sectional view showing a manufacturing step of the fuse transistor in the related art subsequent to FIG. 18.

FIG. 20 is a main portion enlarged cross-sectional view showing a manufacturing step of the fuse transistor in the related art.

FIG. 21 is a main portion enlarged cross-sectional view showing a manufacturing step of the fuse transistor in the related art subsequent to FIG. 20.

FIG. 22 is a cross-sectional view showing the write mechanism of the fuse transistor in the related art.

FIG. 23 is a diagram showing a read current distribution of the fuse transistor in the related art.

FIG. 24 shows cross-sectional view in the gate width direction of the transistor included in the semiconductor device in a modified example.

FIG. 25 is a cross-sectional view showing a manufacturing step in the gate width direction of the transistor included in the semiconductor device in the modified example.

FIG. 26 is a cross-sectional view showing a manufacturing step in the gate width direction of the transistor included in the semiconductor device in the modified example subsequent to FIG. 25.

FIG. 27 is a cross-sectional view showing a manufacturing step in the gate width direction of the transistor included in the semiconductor device in the modified example subsequent to FIG. 26.

FIG. 28 is a cross-sectional view showing a manufacturing step in the gate width direction of the transistor included in the semiconductor device in the modified example subsequent to FIG. 27.

FIG. 29 is a cross-sectional view showing a manufacturing step in the gate width direction of the transistor included in the semiconductor device in the modified example subsequent to FIG. 28.

### DETAILED DESCRIPTION

In all the drawings for explaining the embodiments, the same members are denoted by the same reference numerals in principle, and repetitive descriptions thereof are omitted.

In the following embodiments, “n-type” means n-type conductivity type, and “p-type” means p-type conductivity type. The p-type semiconductor region can be read as a p-type impurity region, and the n-type semiconductor region can be read as an n-type impurity region.

### Embodiment

The semiconductor device in the present embodiment includes a plurality of memory cells disposed in a matrix, and each memory cell (also referred to as a “bit”) includes a selection transistor and a fuse transistor.

### Technical Problems in Related Art

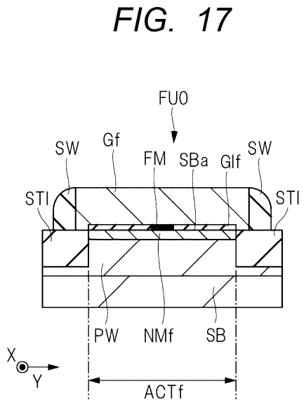

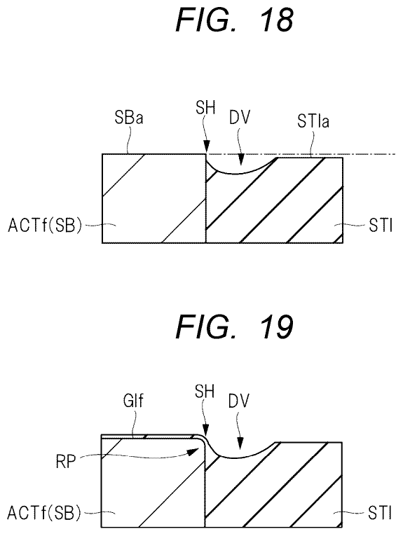

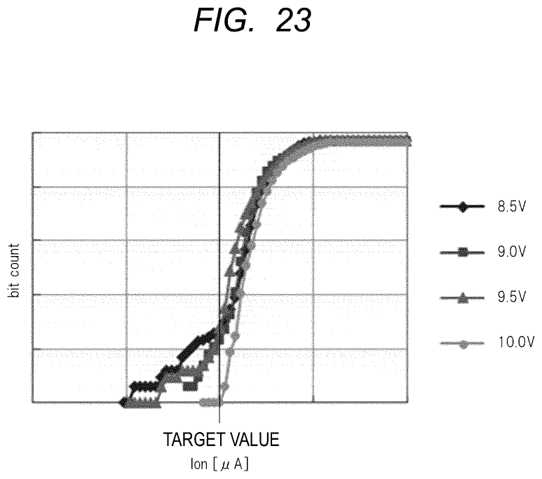

First, the technical problem of the semiconductor device in the related art that the inventors of the present application has confirmed will be described with reference to FIG. 17 to FIG. 23. FIG. 17 is a cross-sectional view in the gate width direction of the fuse transistor in the related art. FIG. 18 to FIG. 21 are main portion enlarged cross-sectional views showing manufacturing steps of the fuse transistor in the related art. FIG. 22 is a cross-sectional view showing the write mechanism of the fuse transistor in the related art. FIG. 23 is a diagram showing a read current distribution of the fuse transistor in the related art.

As shown in FIG. 17, in a fuse transistor FUO in the related art, a gate dielectric film GIf is formed of a single-layer silicon oxide film, and a filament FM is formed in the gate dielectric film GIf. The filament FM is a conductive portion formed between a gate electrode Gf and a semiconductor substrate SB. In an active region ACTf defined by an element isolation film STI, the single-layer gate dielectric film GIf is interposed between the semiconductor substrate SB and the gate electrode Gf. The silicon oxide film is formed by thermally oxidizing the semiconductor substrate formed of silicon.

FIG. 23 shows the relationship between the read current (Ion) and the bit-number (bit count). FIG. 23 shows a read current for a total 70K bit (2K bits×35 chips) in which the filament FM is formed in the gate dielectric film GIf using four write voltages (Vpp=8.5 V, 9.0 V, 9.5 V and 10.0 V). At all write voltages, there is a defective bit whose read current does not reach the target value. When the write voltage is increased, the number of defective bits decreases, but the write voltage cannot be increased any more, and another countermeasure is required. Next, the inventors of the present application examined the cause of occurrence of the defective bit.

Although not shown, the manufacturing step of the fuse transistor FUO includes a step (first step) of forming a trench TR in the semiconductor substrate SB, a step (second step) of forming a dielectric film on the semiconductor substrate SB so as to fill the trench TR, a step (third step) of polishing the dielectric film to form the element isolation film STI, a wet etching step (fourth step) of removing foreign matters formed on a main surface SBa of the semiconductor substrate SB, and a step (fifth step) of forming the gate dielectric film GIf by thermally oxidizing the main surface SBa of the semiconductor substrate SB.

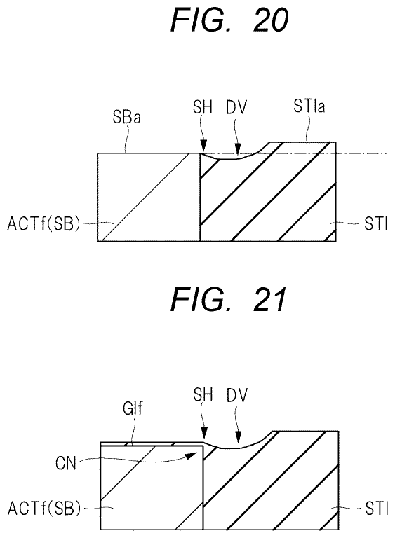

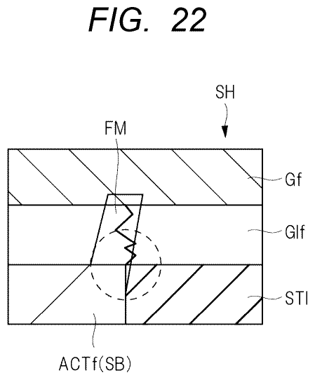

FIG. 18 to FIG. 21 show main portions (on a side of the main surface SBa of the semiconductor substrate SB) between the active region ACTf of the fuse transistor FUO and the element isolation film STI. FIG. 18 and FIG. 20 show the fourth step, and FIG. 19 and FIG. 21 show the fifth step. FIG. 18 and FIG. 19 show cases where a main surface STIa of the element isolation film STI is lower than the main surface SBa of the semiconductor substrate SB (hereinafter, referred to as “low STI”). FIG. 20 and FIG. 21 show cases where the main surface STIa of the element isolation film STI is higher than the main surface SBa of the semiconductor substrate SB (hereinafter referred to as “high STI”). The height differences in the main surface STIa shown in FIGS. 18 and 20 are caused by “in-plane variations” in the polishing step for forming the element isolation film STI (the third step).

As shown in FIG. 18, in the wet etching step (the fourth step described above), a recess DV is generated in the element isolation film STI. In the “low STI”, the sidewall of the semiconductor substrate SB is exposed at a shoulder portion SH of the semiconductor substrate SB in the active region ACTf. On the other hand, as shown in FIG. 20, in the “high STI”, even if the recess DV is generated in the element isolation film STI in the wet etching step (the fourth step described above), the sidewall of the semiconductor substrate SB is not exposed at the shoulder portion SH of the semiconductor substrate SB in the active region ACTf.

Then, as shown in FIG. 19, in the case of “low STI”, in the fifth step, the corner of the shoulder portion SH of the semiconductor substrate SB in the active region ACTf is rounded by oxidization to form a round portion RP. However, as shown in FIG. 21, in the “high STI”, even if the fifth step is performed, the shoulder portion SH of the semiconductor substrate SB in the active region ACTf is not rounded by oxidization, and a substantially right-angled corner portion CN remains. This is because the sidewall of the semiconductor substrate SB is not oxidized at the shoulder portion SH of the semiconductor substrate SB in the active region ACTf.

As shown in FIG. 22, in the “high STI”, the filament FM is formed in the shoulder portion SH of the semiconductor substrate SB in the active region ACTf in the fuse transistor FUO. This is because when a write voltage is applied to the gate electrode Gf, an electric field is concentrated on the corner portion CN, and dielectric breakdown of the gate dielectric film GIf occurs in the shoulder portion SH where the corner portion CN remains. The filament FM formed in the shoulder portion SH of the semiconductor substrate SB in the active region ACTf exhibits high resistivity. This is because formation width of the filament FM is narrower than when the filament FM is formed at a flat position of the semiconductor substrate SB in the active region ACTf.

As described above, the technical problem in the related art is to realize the reduction in the resistivity of the filament FM formed in the fuse transistor FUO without being affected by the “in-plane variation” in the polishing step at the time of forming the element isolation film STI.

### Structure of Semiconductor Device

The semiconductor device in the present embodiment includes a plurality of memory cells disposed in a matrix, and each memory cell (also referred to as a bit) includes a selection transistor and a fuse transistor. The semiconductor device has a logic region including a core transistor in addition to a ROM region (memory region) including a plurality of memory cells. The logic circuit in the logic region is formed by CMOS and includes an n-channel MISFET and a p-channel MISFET, and the n-channel MISFET will be described in the present embodiment.

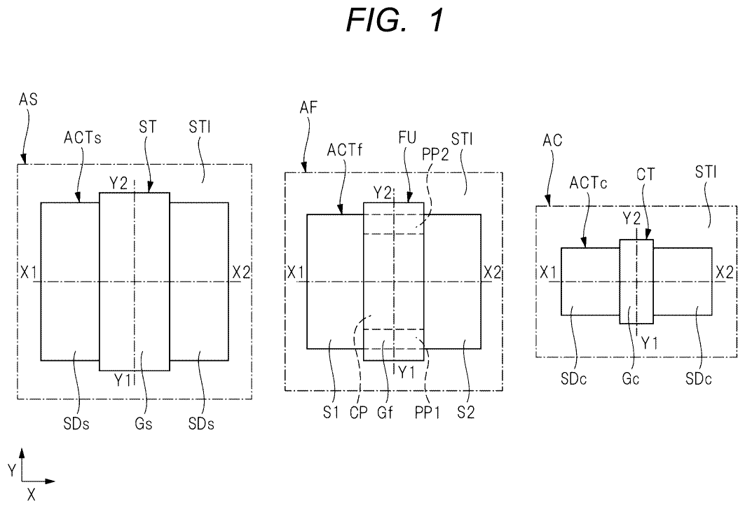

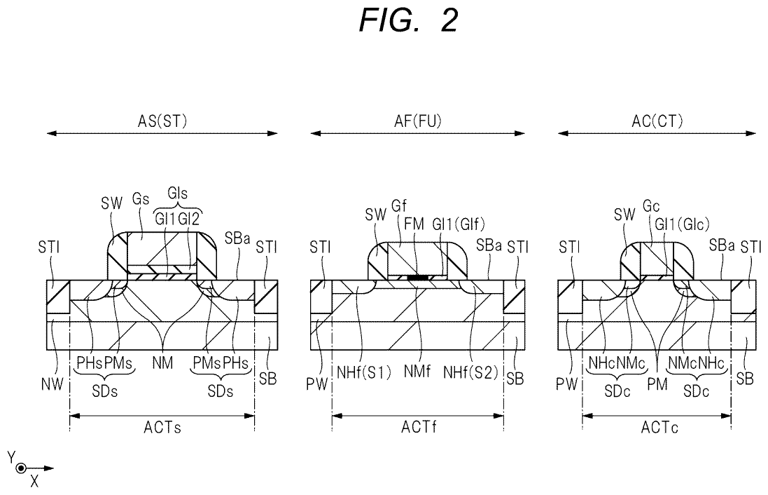

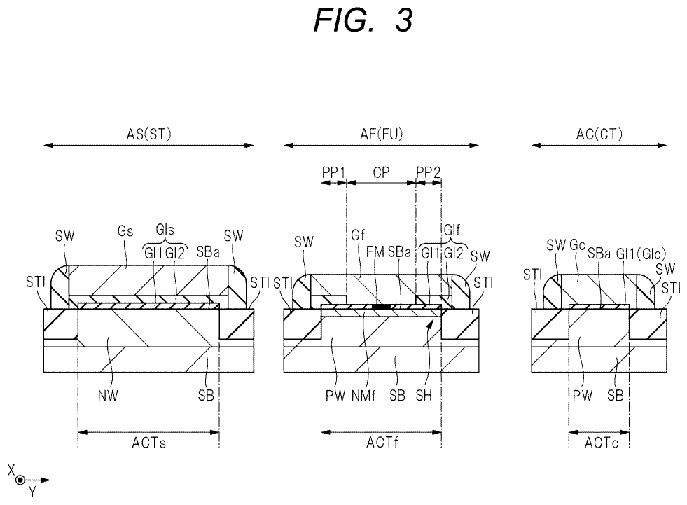

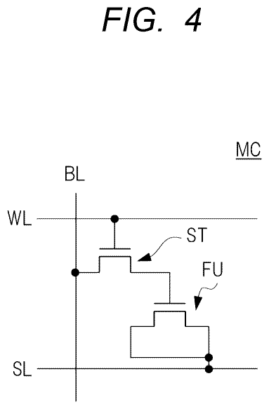

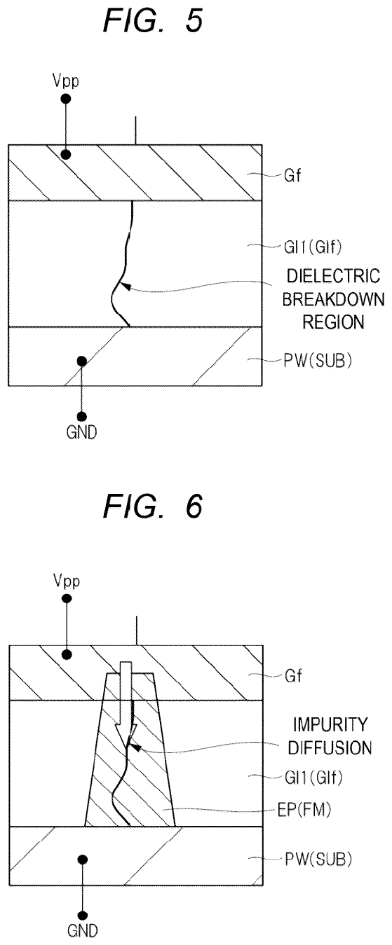

FIG. 1 is a plan view of the transistor included in the semiconductor device in the present embodiment. FIG. 2 is a cross-sectional view of the transistor included in the semiconductor device in the present embodiment. FIG. 3 shows a cross-sectional view in the gate width direction of the transistor included in the semiconductor device in the present embodiment. FIG. 4 is an equivalent circuit diagram of a memory cell portion of the semiconductor device in the present embodiment. FIG. 5 and FIG. 6 are cross-sectional views showing the write mechanism of the fuse transistor in the present embodiment.

As shown in FIG. 1, a region AS is formed of an active region ACTs and the element isolation region, and the element isolation film STI is formed in the element isolation region. A region AF is formed of the active region ACTf and the element isolation region, and the element isolation film STI is formed in the element isolation region. A region AC is formed of an active region ACTc and the element isolation region, and the element isolation film STI is formed in the element isolation region. The region AS includes the active region ACTs of which a perimeter is defined by the element isolation film STI, and a selection transistor ST is formed in the active region ACTs. The region AF includes the active region ACTf of which a perimeter is defined by the element isolation film STI, and a fuse transistor FU is formed in the active region ACTf. The region AC includes the active region ACTc of which a perimeter is defined by the element isolation film STI, and a core transistor CT is included in the active region ACTc. The element isolation film STI extends from the main surface SBa of the semiconductor substrate SB toward the inside of the semiconductor substrate SB (refer to FIGS. 2 and 3).

The selection transistor ST includes a gate electrode Gs extending in the Y direction, and a source region SDs and a drain region SDs disposed on both sides of the gate electrode Gs in the X direction. The fuse transistor FU includes the gate electrode Gf extending in the Y direction, and a pair of source regions S1 and S2 disposed on both sides of the gate electrode Gf in the X direction. The core transistor CT includes a gate electrode Gc extending in the Y direction, and a source region SDc and a drain region SDc disposed on both sides of the gate electrode Gc in the X direction. Here, the X direction is perpendicular to the Y direction, the X direction is the gate length direction of each transistor, and the Y direction is the gate width direction of each transistor.

FIG. 2 is a cross-sectional view along a cutting line X1-X2 in each of the regions AS, AF and AC shown in FIG. 1. The cutting line X1-X2 in the region AS passes through the source region SDs, the gate electrode Gs, and the drain region SDs. The cutting line X1-X2 in the region AF passes through the source region S1, the gate electrode Gf, and the drain region S2. The cutting line X1-X2 in the region AF passes through a central portion CP of the gate dielectric film GIf. The cutting line X1-X2 in the region AC passes through the source region SDc, the gate electrode Gc, and the drain region SDc. As shown in FIG. 2, the selection transistor ST is a p-channel MISFET, and has the p-type gate electrode Gs, a gate dielectric film GIs, the source region SDs, and the drain region SDs. The selection transistor ST is formed in the active region ACTs of which both ends are sandwiched by the element isolation film STI in the X-direction. In the active region ACTs, the gate dielectric film GIs is formed on the main surface SBa of the semiconductor substrate SB, and the gate electrode Gs is formed on the gate dielectric film GIs. The gate dielectric film GIs is formed of a laminated film including a gate dielectric film GI1 and a gate dielectric film GI2 formed on the gate dielectric film GI1. The thickness of the gate dielectric film GI2 is greater (thicker) than the thickness of the underlying gate dielectric film GI1. The gate dielectric film GI2 is formed of a silicon oxide film, and the gate dielectric film GIL is formed of a silicon oxide film or a silicon oxynitride film. The gate electrode Gs is formed of a polycrystalline silicon film into which a p-type impurity is introduced. Sidewall dielectric films SW are formed on the sidewalls of the gate electrode Gs and the gate dielectric film GIs.

In the active region ACTs, the source region SDs and the drain region SDs are disposed on both sides of the gate electrode Gs. The source region SDs and the drain region SDs are formed in the semiconductor substrate SB. Specifically, the source region SDs and the drain region SDs are formed in an n-type well region NW selectively formed in the p-type semiconductor substrate SB. The well region NW is a semiconductor region into which an n-type impurity is introduced. The source region SDs and the drain region SDs include p-type semiconductor regions PHs having a relatively high concentration and p-type semiconductor regions PMs having a relatively low concentration. The source region SDs and the drain region SDs are formed in the semiconductor substrate SB between the gate electrode Gs and the element isolation film STI, respectively. The p-type semiconductor region PHs is disposed on the element isolation film STI side, and the p-type semiconductor region PMs is disposed on the gate electrode Gs side. The p-type semiconductor region PMs is disposed under the sidewall dielectric film SW. A n-type semiconductor region NM is disposed under the p-type semiconductor region PMs. The selection transistor ST may be an n-channel MISFET.

The fuse transistor FU is an n-channel MISFET and has the n-type gate electrode Gf, the gate dielectric film GIf, and a pair of source regions S1 and S2. The fuse transistor FU is formed in the active region ACTf of which both ends are defined by the element isolation film STI in the X-direction. In the active region ACTf, the gate dielectric film GIf is formed on the main surface SBa of the semiconductor substrate SB, and the gate electrode Gf is formed on the gate dielectric film GIf. In the cross section in the X-direction, the gate dielectric film GIf is formed of the gate dielectric film GI1. The gate dielectric film GI1 is formed of a silicon oxide film or a silicon oxynitride film. The gate electrode Gf is formed of a polycrystalline silicon film into which an n-type impurity (for example, phosphorus) is introduced. The sidewall dielectric films SW are formed on the sidewalls of the gate electrode Gf and the gate dielectric film GIf. The filament FM is formed in the gate dielectric film GIf. In the ROM region, there is also the fuse transistor FU in which the filament FM is not formed. In addition, there is no filament FM in the fuse transistor FU when no data is written to the memory cell.

In the active region ACTf, a pair of source regions S1 and S2 are disposed on both sides of the gate electrode Gf. The pair of source regions S1 and S2 are formed in the semiconductor substrate SB. Specifically, the pair of source regions S1 and S2 are formed in a p-type well region PW selectively formed in the p-type semiconductor substrate SB. The well region PW is a semiconductor region into which a p-type impurity is introduced. Each of the pair of source regions S1 and S2 is formed of n-type semiconductor region NHf having relatively high concentration. A n-type semiconductor region NMf having relatively low concentration is formed between the pair of source regions S1 and S2.

The core transistor CT is an n-channel MISFET and has the n-type gate electrode Gc, a gate dielectric film GIc, the source region SDc, and the drain region SDc. The selection transistor CT is formed in the active region ACTc of which both ends are defined by the element isolation film STI in the X-direction. In the active region ACTc, the gate dielectric film GIc is formed on the main surface SBa of the semiconductor substrate SB, and the gate electrode Gc is formed on the gate dielectric film GIc. The gate dielectric film GIc is formed of the gate dielectric film GI1. The gate dielectric film GIL is formed of a silicon oxide film or a silicon oxynitride film. The gate electrode Gc is formed of a polycrystalline silicon film into which an n-type impurity is introduced. The sidewall dielectric films SW are formed on the sidewalls of the gate electrode Gc and the gate dielectric film GIc.

In the active region ACTc, the source region SDc and the drain region SDc are disposed on both sides of the gate electrode Gc. The source region SDc and the drain region SDc are formed in the semiconductor substrate SB. Specifically, the source region SDc and the drain region SDc are formed in the p-type well region PW selectively formed in the p-type semiconductor substrate SB. The well region PW is a semiconductor region into which a p-type impurity is introduced. The source region SDc and the drain region SDc include n-type semiconductor regions NHc having relatively high concentration and n-type semiconductor regions NMc having relatively low concentration. The source region SDc and the drain region SDc are formed in the semiconductor substrate SB between the gate electrode Gc and the element isolation film STI, respectively. The n-type semiconductor region NHc is disposed on the element isolation film STI side, and the n-type semiconductor region NMc is disposed on the gate electrode Gc side. The n-type semiconductor region NMc is disposed under the sidewall dielectric film SW. A p-type semiconductor region PM is disposed under the n-type semiconductor region NMc.

Here, since the power-supply voltage Vds (for example, 10 V) applied to the gate electrode Gs of the selection transistor ST is higher than the power-supply voltage Vdc (for example, 1.5 V) applied to the gate electrode Gc of the core transistor CT, the gate length Lgs of the selection transistor ST is greater than the gate length Lgc of the core transistor CT. In addition, the thickness of the gate dielectric film GIs of the selection transistor ST is greater (thicker) than the thickness of the gate dielectric film GIc of the core transistor CT. The thickness of the central portion CP of the gate dielectric film GIf of the fuse transistor FU is equal to the thickness of the gate dielectric film GIc of the core transistor CT.

FIG. 3 is a cross-sectional view along a cutting line Y1-Y2 in each of the regions AS, AF and AC shown in FIG. 1. In the regions AS, AF and AC, the cutting lines Y1-Y2 pass through the respective gate electrodes Gs, Gf and Gc. As shown in FIG. 3, the selection transistor ST is formed in the active region ACTs of which both ends are defined by the element isolation film STI in the Y-direction. In the active region ACTs, the gate dielectric film GIs is formed on the main surface SBa of the semiconductor substrate SB, and the gate electrode Gs is formed on the gate dielectric film GIs. The gate dielectric film GIs is formed of a laminated film including the gate dielectric film GI1 and the gate dielectric film GI2 formed on the gate dielectric film GI1. The thickness of the gate dielectric film GI2 is greater than the thickness of the gate dielectric film GI1. In the Y-direction, the gate dielectric film GI1 in the active region ACTs covers the entire main surface SBa of the semiconductor substrate SB and reaches and terminates in the element isolation films STI disposed on both sides of the active region ACTs. In the Y-direction, the gate dielectric film GI2 in the active region ACTs covers the entire main surface SBa of the semiconductor substrate SB and reaches the element isolation films STI disposed on both sides of the active region ACTs, and terminates on the element isolation films STI. Further, in the Y-direction, the gate electrode Gs in the active region ACTs covers the entire main surface SBa of the semiconductor substrate SB and reaches the element isolation films STI disposed on both sides of the active region ACTs, and terminates on the element isolation films STI. The gate dielectric film GIs is interposed between the gate electrode Gs and the main surface SBa of the semiconductor substrate SB in the entire region of the gate electrode Gs located in the active region ACTs.

The fuse transistor FU is formed in the active region ACTf of which both ends are defined by the element isolation film STI in the Y-direction. In the active region ACT, the gate dielectric film GIf is formed on the main surface SBa of the semiconductor substrate SB, and the gate electrode Gf is formed on the gate dielectric film GIf. In the Y-direction, the gate dielectric film GIf has the central portion CP and peripheral portions PP1 and PP2. In plan view, the central portion CP and the peripheral portions PP1, and PP2 are located in the active region ACTf. In the Y-direction, the central portion CP is spaced apart from the element isolation film STI, and the peripheral portions PP1 or PP2 are interposed between the central portion CP and the element isolation film STI. The main surface SBa of the semiconductor substrate SB has a flat surface under the central portion CP. The central portion CP of the gate dielectric film GIf is formed of the single-layer gate dielectric film GI1, and the peripheral portions PP1 and PP2 are formed of a laminated film including the gate dielectric film GI1 and the gate dielectric film GI2 formed on the gate dielectric film GI1. The thickness of the gate dielectric film GI2 is greater (thicker) than the thickness of the gate dielectric film GI1. The thickness of each of the peripheral portions PP1 and PP2 of the gate dielectric film GIf is greater (thicker) than the thickness of the gate dielectric film GIf in the central portion CP. In the Y-direction, the gate dielectric film GI1 in the active region ACTf covers the entire main surface SBa of the semiconductor substrate SB and reaches and terminates in the element isolation films STI disposed on both sides of the active region ACTf. In the Y-direction, the gate dielectric film GI2 in the active region ACTf covers a portion of the main surface SBa of the semiconductor substrate SB, reaches the element isolation films STI disposed on both sides of the active region ACTf, and terminates on the element isolation film STI. Note that the central portion CP of the gate dielectric film GIf is a region in which the filament FM is formed, and the filament FM is formed in the central portion CP of the gate dielectric film GIf as shown in FIG. 3. Further, in the Y-direction, the gate electrode Gf in the active region ACTf covers the entire main surface SBa of the semiconductor substrate SB, reaches the element isolation films STI disposed on both sides of the active region ACTf, and terminates on the element isolation film STI. The gate dielectric film GIf is interposed between the gate electrode Gf and the main surface SBa of the semiconductor substrate SB in the entire region of the gate electrode Gf located in the active region ACTf.

The widths W of the peripheral portions PP1 and PP2 are preferably 50 nm or more and 100 nm or less. The peripheral portions PP1 and PP2 can cover the shoulder portion SH shown in FIG. 19 or FIG. 21 by setting the widths W of the peripheral portions PP1 and PP2 to be 50 nm or more. As a consequence, the central portion CP, which is the forming region of the filament FM, can be spaced apart from the shoulder portion SH. That is, the central portion CP can be disposed in a flat region of the main surface SBa of the semiconductor substrate SB. Further, by setting the widths W of the peripheral portions PP1 and PP2 to be 100 nm or less, the width of the central portion CP can be sufficiently secured while the fuse transistor FU is miniaturized.

The core transistor CT is formed in the active region ACTc of which both ends are defined by the element isolation film STI in the Y-direction. In the active region ACTc, the gate dielectric film GIc is formed on the main surface SBa of the semiconductor substrate SB, and the gate electrode Gc is formed on the gate dielectric film GIc. The gate dielectric film GIc is formed of the gate dielectric film GI1. In the Y-direction, the gate dielectric film GIc covers the entire main surface SBa of the semiconductor substrate SB in the active region ACTc. In the Y-direction, the gate dielectric film GIL in the active region ACTc covers the entire main surface SBa of the semiconductor substrate SB and reaches and terminates in the element isolation films STI disposed on both sides of the active region ACTc. Further, in the Y-direction, the gate electrode Gc in the active region ACTc covers the entire main surface SBa of the semiconductor substrate SB, reaches the element isolation films STI disposed on both sides of the active region ACTc, and terminates on the element isolation film STI. The gate dielectric film GIc is interposed between the gate electrode Gc and the main surface SBa of the semiconductor substrate SB in the entire region of the gate electrode Gc located in the active region ACTc.

That is, the thickness of the gate dielectric film GIf of the fuse transistor FU at the central portion CP is equal to the thickness of the gate dielectric film GIc of the core transistor CT and is smaller than the thickness of the gate dielectric film GIs of the selection transistor ST. The thickness of each of the peripheral portions PP1 and PP2 of the gate dielectric film GIf of the fuse transistor FU is equal to the thickness of the gate dielectric film GIs of the selection transistor ST and is greater than the thickness of the gate dielectric film GIc of the core transistor CT.

As shown in FIG. 4, a memory cell MC includes the selection transistor ST and the fuse transistor FU. Referring to FIG. 2, one of the source region SDs and the drain region SDs of the selection transistor ST is connected to a bit line BL, and the other of the source region SDs and the drain region SDs is connected to the gate electrode Gf of the fuse transistor FU. The gate electrode Gs of the selection transistor ST is connected to a word line WL. The pair of source regions S1 and S2 of the fuse transistor FU are connected to a source line SL. At the time of writing, the selection transistor ST is made conductive, and the write voltage Vpp (for example, 10 V) of the bit line BL is applied to the gate electrode Gf of the fuse transistor FU, so that the filament FM is formed in the central portion CP of the gate dielectric film GIf. At the time of reading, the selection transistor ST is made conductive, and the read voltage Vre (for example, 1.5 V) of the bit line BL is applied to the gate electrode Gf of the fuse transistor FU. Then, the read current flowing from the bit line BL to the source line SL via the filament FM formed in the gate dielectric film GIf is measured to determine the data (“0” or “1”) of the memory cell MC. Therefore, in order to improve the readout accuracy, it is essential to reduce the resistivity of the filament FM.

Next, the write mechanism of the fuse transistor FU will be described with reference to FIGS. 5 and 6. As shown in FIG. 5, when the write voltage Vpp (for example, 10 V) is applied to the gate electrode Gf and a potential difference is generated between the gate electrode Gf and the well region PW, a dielectric breakdown region is formed in the gate dielectric film GIf. The dielectric breakdown region reaches the well region PW from the gate electrode Gf, and a write current flows from the gate electrode Gf to the well region PW. As the write current continues to flow in the high-resistivity dielectric breakdown region, the breakdown region becomes a high temperature, and as shown in FIG. 6, an epitaxial layer EP grows from the semiconductor substrate SB toward the gate electrode Gf. That is, the epitaxial layer EP formed of a silicon layer is formed around the dielectric breakdown region, and the epitaxial layer EP reaches the gate electrode Gf from the semiconductor substrate SB. Further, phosphorus (P) contained in the gate electrode Gf is diffused into the epitaxial layer EP, so that the low-resistivity filament FM is formed. In order to reduce the resistivity of the filament FM, it is essential to widen the width of the filament FM. As shown in FIG. 3, since the central portion CP, which is the forming region of the filament FM, is spaced apart from the shoulder portion SH and the central portion CP is disposed in the flat region of the main surface SBa of the semiconductor substrate SB, the width of the filament FM can be widened. Then, the filament FM can be made low resistivity.

### Manufacturing Method of Semiconductor Device

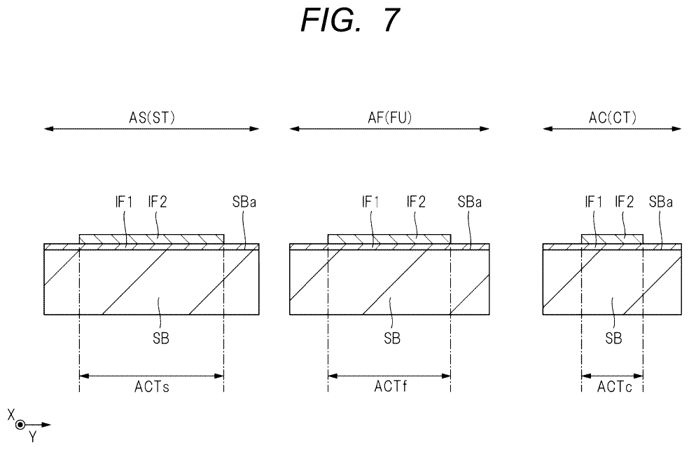

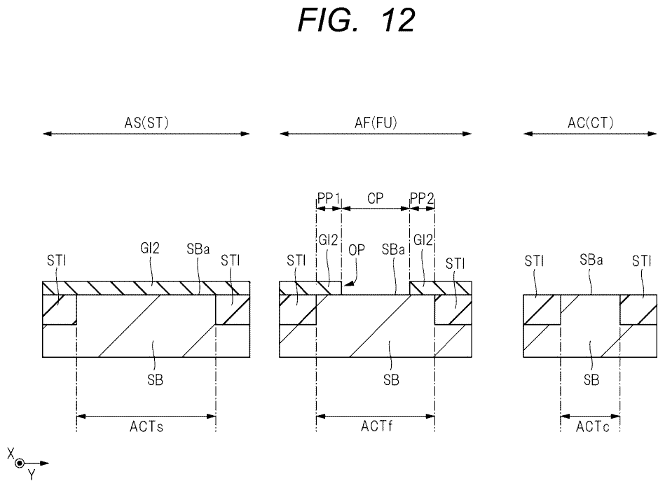

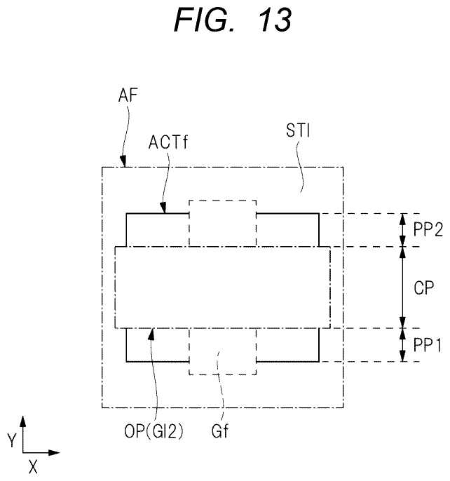

The manufacturing method of the semiconductor device in the present embodiment will be described with reference to FIGS. 7 to 16. FIG. 7 to FIG. 12 and FIG. 14 to FIG. 16 are cross-sectional views showing the manufacturing steps in the gate width direction of the transistors included in the semiconductor device in the present embodiment. FIG. 13 is a plan view of the fuse transistor in the manufacturing step shown in FIG. 12. In the following description, a step of forming the gate electrodes Gs, Gf and Gc will be described, and a step of forming the well regions NW and PW and the semiconductor region NMf shown in FIG. 2 will not be described and shown.

As shown in FIG. 7, a dielectric film IF2 is formed in the regions AS, AF and AC. A dielectric film IF1 formed of a silicon oxide film is formed on the main surface SBa of the semiconductor substrate SB, and then the dielectric film IF2 formed of a silicon nitride film is formed on the dielectric film IF1. The dielectric film IF2 has a pattern corresponding to the active regions ACTs, ACTf and ACTc. The dielectric film IF2 covers a portion of the main surface SBa of the semiconductor substrate SB located in the region in which the active region ACTs is defined in the region AS, and exposes the outer side of the region in which the active region ACTs is defined. In addition, the dielectric film IF2 covers a portion of the main surface SBa of the semiconductor substrate SB located in the region in which the active region ACTf is defined in the region AF, and exposes the outer side of the region in which the active region ACTf is defined. The dielectric film IF2 covers a portion of the main surface SBa of the semiconductor substrate SB located in the region in which the active region ACTc is defined in the region AC, and exposes the outer side of the region in which the active region ACTc is defined.

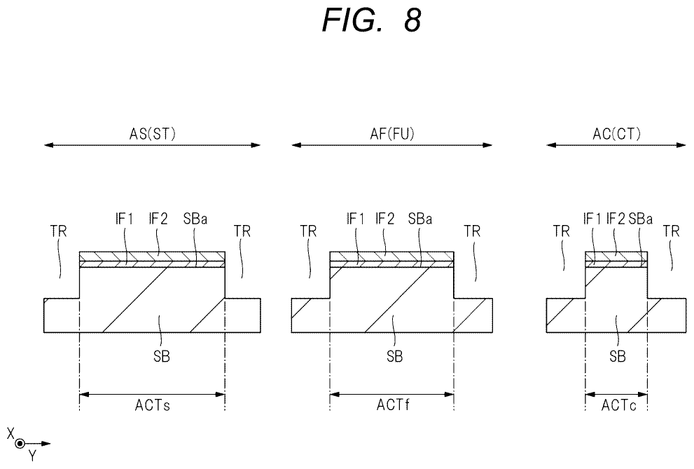

Next, as shown in FIG. 8, the trench TR is formed in the regions AS, AF and AC. In the regions AS, AF and AC, the trench TR is formed in the semiconductor substrate SB in the regions exposed from the dielectric film IF2. The trench TR extends toward the inside of the semiconductor substrate SB from the main surface SBa of the semiconductor substrate SB, and has a depth of, for example, about 0.4 micrometers. In cross-sectional view, the trench TR extends in a direction perpendicular to the main surface SBa. Note that this step corresponds to the first step described above.

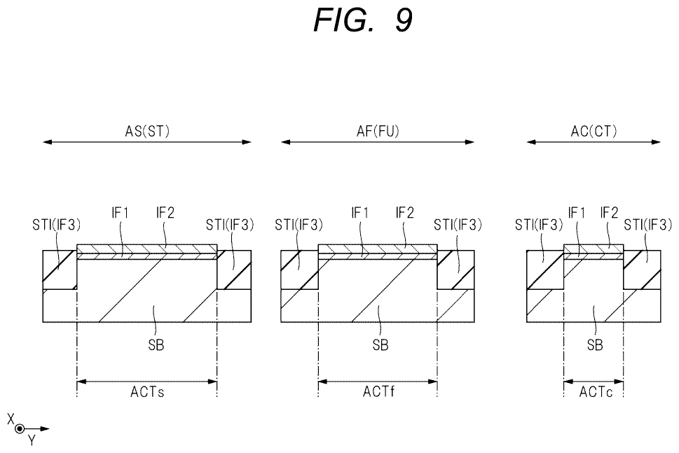

Next, as shown in FIG. 9, the element isolation film STI is formed in the regions AS, AF and AC. In order to completely fill the trench TR shown in FIG. 8, a dielectric film IF3 is formed in the trench TR and on the dielectric film IF2. Note that this step corresponds to the second step described above. Next, the dielectric film IF3 is subjected to a polishing process called CMP to form the element isolation film STI. That is, the dielectric film IF3 is left in the trench TR and the dielectric film IF3 on the dielectric film IF2 is removed by the polishing process. FIG. 9 is a cross-sectional view after polishing process. Note that this step corresponds to the third step described above.

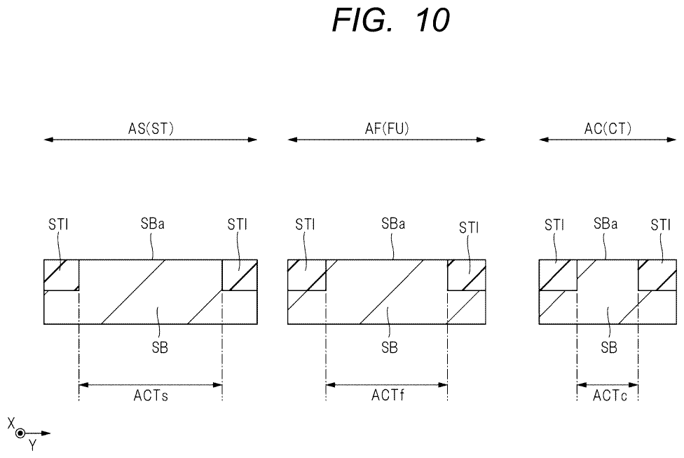

Next, as shown in FIG. 10, the main surface SBa of the semiconductor substrate SB is exposed in the regions AS, AF and AC. That is, the dielectric films IF2 and IF1 shown in FIG. 9 are removed to expose the main surface SBa of the semiconductor substrate SB. In this way, the active regions ACTs, ACTf and a ACTc of which peripheries are defined by the element isolation film STI are prepared.

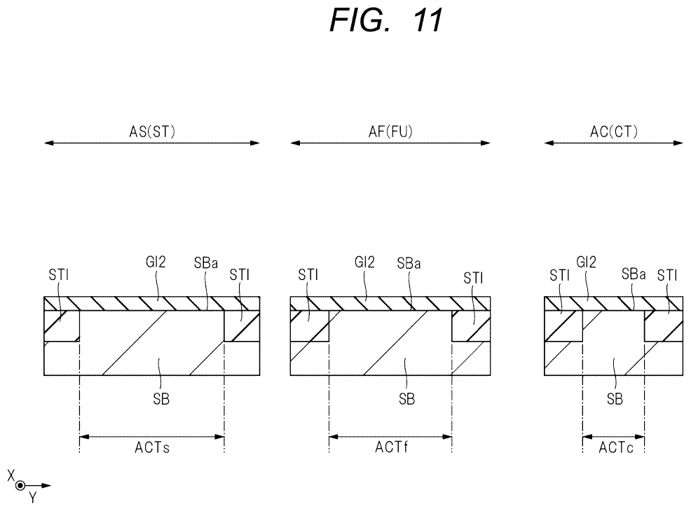

Next, as shown in FIG. 11, the gate dielectric film GI2 is formed in the regions AS, AF and AC. The gate dielectric film GI2 is formed on the main surface SBa of the semiconductor substrate SB and on the element isolation film STI using CVD (Chemical Vapor Deposition) method.

Next, as shown in FIG. 12, the gate dielectric film GI2 is removed in the regions AF and AC. In the region AF, the central portion CP of the gate dielectric film GI2 is removed to expose the main surface SBa of the semiconductor substrate SB. However, the peripheral portions PP1 and PP2 of the gate dielectric film GI2 and the gate dielectric film GI2 on the element isolation film STI are left without being removed. That is, an opening portion OP is formed at a position corresponding to the central portion CP of the gate dielectric film GI2. That is, by removing a portion of the gate dielectric film GI2 that is spaced apart from the element isolation film STI in the Y-direction, the opening portion OP that exposes the main surface SBa is formed. In addition, the gate dielectric film GI2 in the region AC is removed to expose the main surface SBa of the semiconductor substrate SB and the element isolation film STI. However, in the region AS, the gate dielectric film GI2 is left without being removed. Note that this step corresponds to the fourth step described above.

FIG. 13 is a plan view corresponding to a step of removing the gate dielectric film GI2 shown in FIG. 12. The width of the opening portion OP formed in the gate dielectric film GI2 in the region AF is smaller than the width of the active region ACTf in the Y-direction. Then, in the Y-direction, the opening portion OP is spaced apart from one element isolation film STI by the width of the peripheral portion PP1, and is spaced apart from the other element isolation film STI by the width of the peripheral portion PP2.

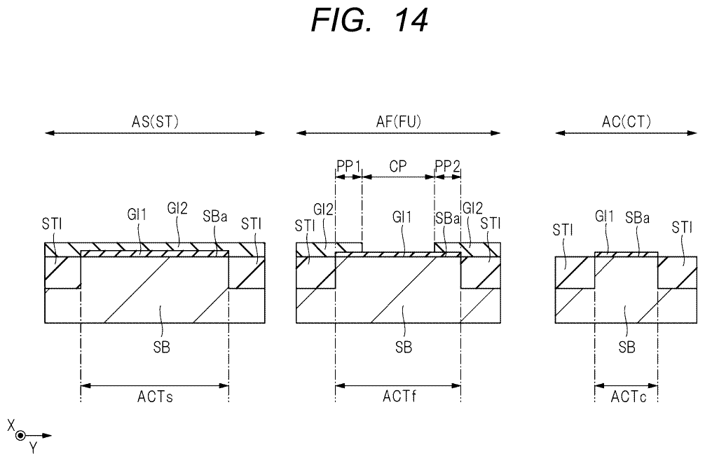

Next, as shown in FIG. 14, the gate dielectric film GI1 is formed in the regions AS, AF and AC. The gate dielectric film GI1 is formed by a thermal oxidation process. In the region AS, the gate dielectric film GIL is formed between the semiconductor substrate SB and the gate dielectric film GI2 over the entire active region ACTs. In the region AF, the gate dielectric film GI1 is formed over the entire region of the active region ACTf, and the gate dielectric film GIL is formed on the main surface SBa of the semiconductor substrate SB exposed from the opening portion OP and between the peripheral portions PP1 and PP2 of the gate dielectric film GI2 and the main surface SBa of the semiconductor substrate. That is, the gate dielectric film GI1 is formed on the main surface SBa exposed from the opening portion OP and between the semiconductor substrate SB and the gate dielectric film GI2. In the region AC, the gate dielectric film GI1 is formed on the main surface SBa of the semiconductor substrate SB over the entire region of the active region ACTc. Note that this step corresponds to the fifth step described above.

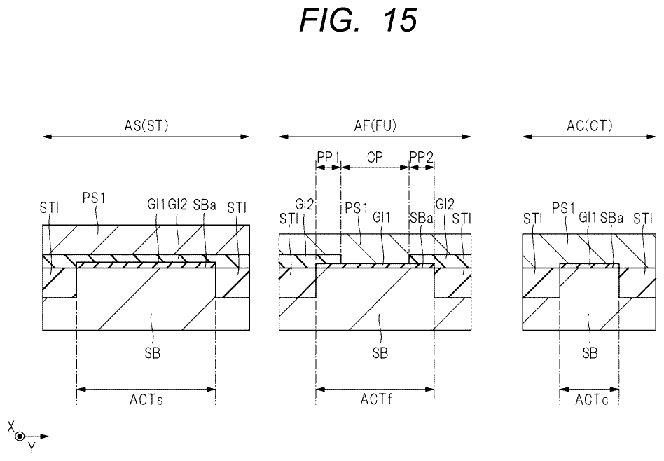

Next, as shown in FIG. 15, a polycrystalline silicon film PS1 is formed in the regions AS, AF and AC. The polycrystalline silicon film PS1 is formed on the gate dielectric film GI2 in the region AS, is formed on the gate dielectric films GI1 and GI2 in the region AF, and is formed on the gate dielectric film GI1 in the region AC.

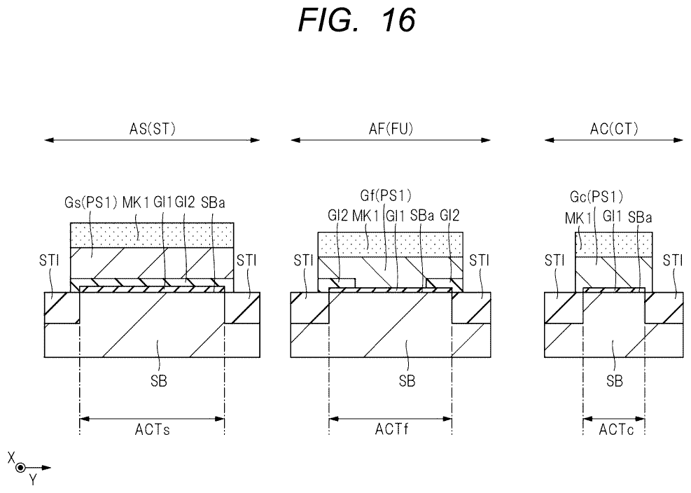

Next, as shown in FIG. 16, the polycrystalline silicon film PS1 and the gate dielectric film GI2 are processed using a mask film MK1. That is, the gate electrode Gs is formed in the region AS, the gate electrode Gf is formed in the region AF, and the gate electrode Gc is formed in the region AC.

Next, in the regions AS, the sidewall dielectric films SW are formed on the sidewall of the gate electrode Gs and the sidewall of the gate dielectric film GI2. In the region AF, the sidewall dielectric films SW are formed on the sidewall of the gate electrode Gf and the sidewall of the gate dielectric film GI2, and the sidewall dielectric film SW is formed on the sidewall of the gate electrode Gc in the region AC. Thus, the selection transistor ST, the fuse transistor FU, and the core transistor CT shown in FIGS. 2 and 3 are manufactured.

### Features of Semiconductor Device in Present Embodiment

The semiconductor device in the present embodiment has the following features.

The filament FM forming region of the fuse transistor FU is located the central portion CP of the gate dielectric film GIf. Under the central portion CP, the main surface SBa of the semiconductor substrate SB has a flat surface, so that the formation width of the filament FM can be widened. Consequently, the filament FM can be reduced in resistivity. Therefore, the read current of the fuse transistor FU can be increased, and the reliability of the semiconductor device can be improved.

In the fuse transistor FU, the peripheral portions PP1 and PP2 are disposed on both sides of the central portion CP of the gate dielectric film GIf. The thickness of each of the peripheral portions PP1 and PP2 of the gate dielectric film GIf is greater (thicker) than the thickness of the central portion CP of the gate dielectric film GIf. In addition, the peripheral portions PP1 and PP2 reach the element isolation film STI. Therefore, when the fuse transistor FU is written, dielectric breakdown of the gate dielectric film GIf does not occur in the shoulder portion SH of the semiconductor substrate SB in the active region ACTf.

Therefore, even if processing variation due to “in-plane variation” occurs in the manufacturing step of the semiconductor device, dielectric breakdown of the gate dielectric film GIf can be prevented in the shoulder portion SH of the semiconductor substrate SB in the active region ACTf, and thus the manufacturing yield is improved. For example, the polishing process in a step of forming the element isolation film STI causes the height variation of the main surface STIa of the element isolation film STI. However, according to the semiconductor device in the present embodiment, it is possible to prevent the filament FM from increasing in resistivity due to the height variation in the main surface STIa of the element isolation film STI.

The peripheral portions PP1 and PP2 of the gate dielectric film GIf of the fuse transistor FU are the same as those of the gate dielectric film GIs of the selection transistor ST. That is, the peripheral portions PP1 and PP2 of the gate dielectric film GIf can be formed without adding a new process.

### Modified Example

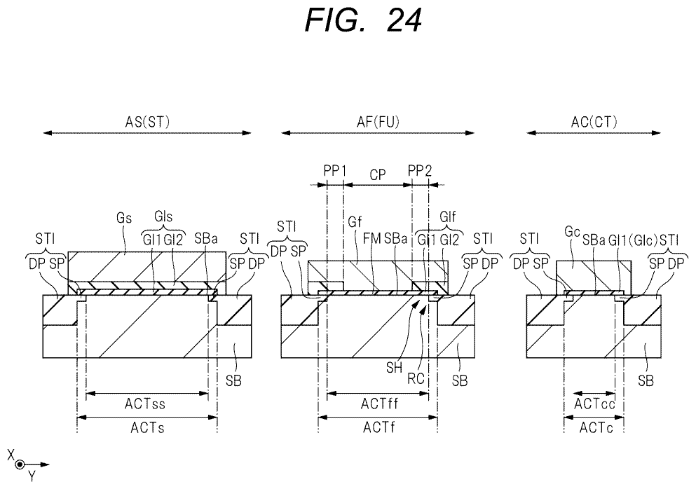

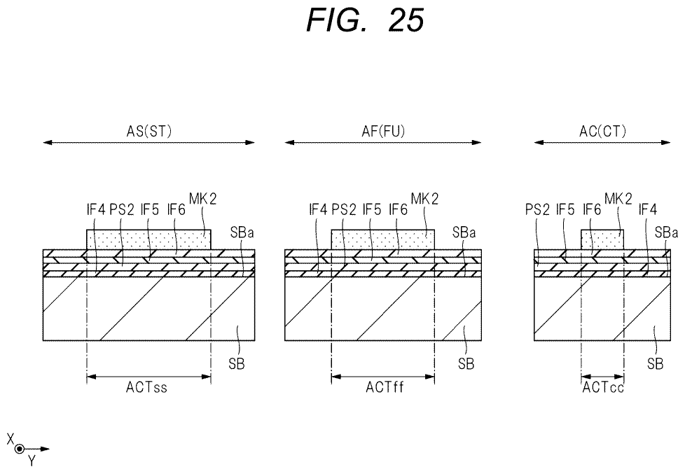

The modified example relates to an element isolation film and a manufacturing method thereof in the above embodiment. FIG. 24 is a cross-sectional view in the gate width direction of the transistor included in the semiconductor device in the modified example, and corresponds to FIG. 16 in the above-described embodiment. However, illustration of the mask film MK1 is omitted. FIG. 25 to FIG. 29 are cross-sectional views showing a manufacturing step of the transistor included in the semiconductor device in the modified example.

As shown in FIG. 24, the element isolation film STI in the modified example has a shallow portion SP and a deep portion DP. The shallow portion SP is shallower than the deep portion DP. Accordingly, in the regions AS, AF and AC, the widths of active regions ACTss, ACTff and ACTcc in the Y-direction are narrower than the widths of the active regions ACTs, ACTf and ACTc in the above-described embodiment. Configurations other than the element isolation film STI and the active regions ACTss, ACTff and ACTcc are the same as those in the above-described embodiment, and therefore, the explanation of the selection transistor ST and the core transistor CT is omitted.

As shown in FIG. 24, in the fuse transistor FU, the gate dielectric film GIf has the central portion CP and the peripheral portions PP1 and PP2. In plan view, the central portion CP and the peripheral portions PP1 and PP2 are both located in the active region ACTff sandwiched between the element isolation films STI. In the Y-direction, the central portion CP is spaced apart from the element isolation film STI, and the peripheral portions PP1 and PP2 is interposed between the central portion CP and the element isolation film STI. The main surface SBa of the semiconductor substrate SB has a flat surface under the central portion CP. The central portion CP of the gate dielectric film GIf is formed of the single-layer gate dielectric film GI1, and the peripheral portions PP1 and PP2 are formed of a laminated film including the gate dielectric film GI1 and the gate dielectric film GI2 formed on the gate dielectric film GI1. The thickness of the gate dielectric film GI2 is greater (thicker) than the thickness of the gate dielectric film GI1. The thickness of each of the peripheral portions PP1 and PP2 of the gate dielectric film GIf is greater (thicker) than the thickness of the central portion CP of the gate dielectric film GIf. In the Y-direction, the gate dielectric film GIf covers the entire main surface SBa of the semiconductor substrate SB in the active region ACTff. In the Y-direction, the gate dielectric film GI1 covers the entire main surface SBa of the semiconductor substrate SB in the active region ACTff, and reaches and terminates in the shallow portion SP of the element isolation film STI disposed on both sides of the active region ACTff. In the Y-direction, the gate dielectric film GI2 covers a portion of the main surface SBa of the semiconductor substrate SB in the active region ACTff, reaches the shallow portion SP of the element isolation film STI disposed on both sides of the active region ACTff, and terminates on the deep portion DP of the element isolation film STI. The central portion CP of the gate dielectric film GIf is a region where the filament FM is formed.

The central portion CP of the gate dielectric film GIf in which the filament FM is formed is spaced apart from the element isolation film STI. Therefore, during the formation of the filament FM (during writing), the formation of the filament FM is not affected by a recess RC present on the shoulder portion SH of the semiconductor substrate SB in the active region ACTff. In the fuse transistor FU, no filament FM is formed in the shoulder portion SH of the semiconductor substrate SB in the active region ACTff. The filament FM can have a low resistivity because the filament FM is formed in the central portion CP on the main surface SBa of the semiconductor substrate SB, which is a flat surface.

Next, a manufacturing step in the gate width direction of the transistor included in the semiconductor device in the modified example will be described with reference to FIG. 25 to FIG. 29. The manufacturing method of the semiconductor device in the modified example replaces the manufacturing steps shown in FIGS. 7 to 10 in the above embodiment with the manufacturing steps shown in FIGS. 25 to 29.

As shown in FIG. 25, in the regions AS, AF and AC, a dielectric film IF4, a polycrystalline silicon film PS2, a dielectric film IF5, and a dielectric film IF6 are formed in this order on the main surface SBa of the semiconductor substrate SB. Each of the dielectric films IF4 and IF5 is a silicon oxide film, and the dielectric film IF6 is a silicon nitride film. Next, in the regions AS, AF and AC, a mask film MK2 is formed on the dielectric film IF6 to selectively cover a portion (one region) of the main surface SBa of the semiconductor substrate SB located in the region in which the respective active regions ACTss, ACTff and ACTcc are defined.

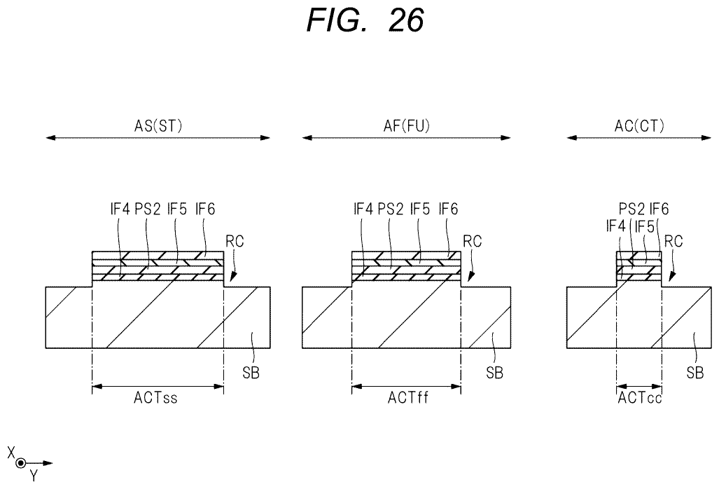

Next, as shown in FIG. 26, the dielectric film IF6, the dielectric film IF5, the polycrystalline silicon film PS2, and the dielectric film IF4 located in the regions exposed from the mask film MK2 shown in FIG. 25 are sequentially etched and removed, and the recess RC is further formed in the semiconductor substrate SB.

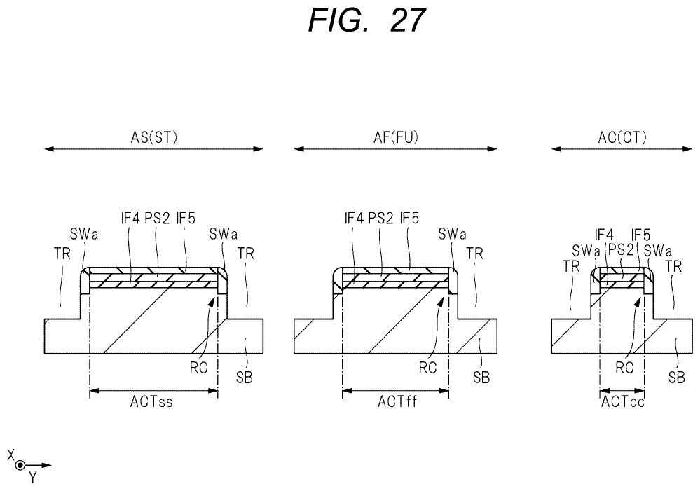

Next, the dielectric film IF6 is removed in the regions AS, AF and AC. Then, as shown in FIG. 27, in the regions AS, AF and AC, sidewall dielectric films SWa are formed on the sidewalls of the laminated body including the dielectric film IF4, the polycrystalline silicon film PS2, and the dielectric film IF5. Next, the trench TR is formed in the semiconductor substrate SB in regions exposed from the laminated body including the dielectric film IF4, the polycrystalline silicon film PS2, and the dielectric film IF5, and the sidewall dielectric films SWa. That is, the trench TR is formed in the semiconductor substrate SB at the bottom surface of the recess RC exposed from the laminated body including the dielectric film IF4, the polycrystalline silicon film PS2, and the dielectric film IF5, and the sidewall dielectric films SWa.

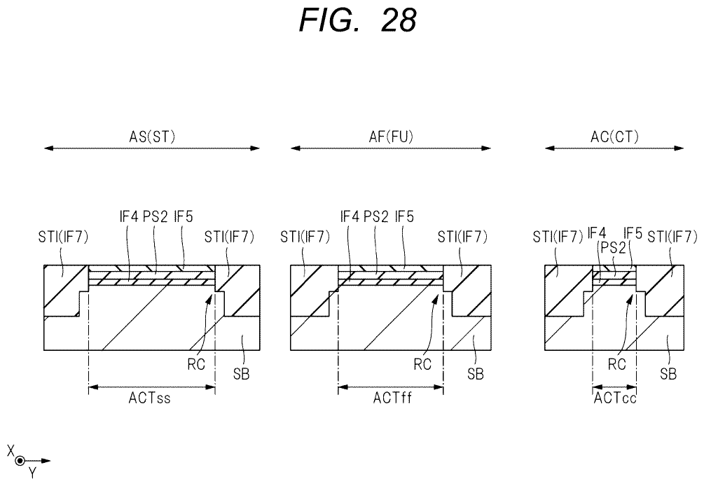

Next, as shown in FIG. 28, the element isolation film STI is formed in the regions AS, AF and AC. First, in the regions AS, AF and AC, after removing the sidewall dielectric films SWa, a dielectric film IF7 is formed on the dielectric film IF5 so as to completely fill the trench TR. Next, the dielectric film IF7 is subjected to a polishing process called CMP to form the element isolation film STI. That is, the dielectric film IF7 is left in the trench TR and the recess RC by the polishing process, and the dielectric film IF7 on the dielectric film IF5 is removed. FIG. 28 is a cross-sectional view after polishing process.

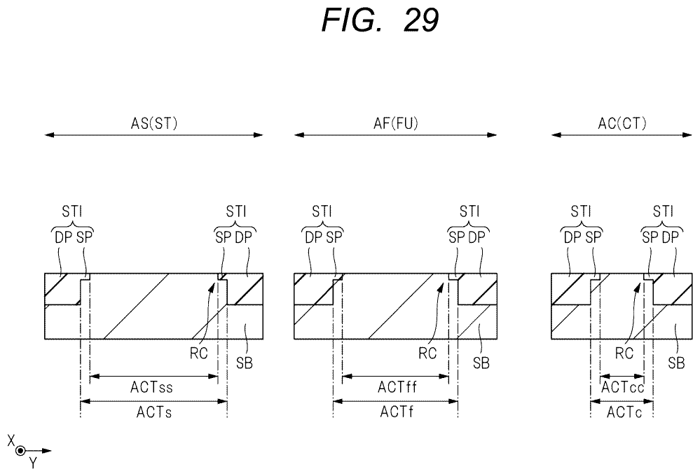

Next, in the regions AS, AF and AC, the dielectric film IF5, the polycrystalline silicon film PS2, and the dielectric film IF4 are sequentially etched and removed, and the element isolation film STI is further etched to adjust the height of the element isolation film STI. Through the above steps, the element isolation film STI shown in FIG. 29 is formed. The element isolation film STI has the shallow portion SP and the deep portion DP. The shallow portion SP is disposed between each of the active regions ACTss, ACTff and ACTcc and the deep portion DP in the Y-direction. The active regions ACTss, ACTff and ACTcc are defined by the shallow portion SP of the element isolation film STI. Next, the semiconductor device of the modified example can be manufactured by performing the steps of FIG. 11 and subsequent steps described in the above embodiment.

Although the invention made by the present inventors has been specifically described based on the embodiments, the present invention is not limited to the above-described embodiments, and it is needless to say that various changes can be made without departing from the gist thereof.

What is claimed is:

1. A semiconductor device comprising:
a semiconductor substrate having a main surface;
a first element isolation film and a second element isolation film each extending from the main surface toward an inside of the semiconductor substrate, the first element isolation film and the second element isolation film being disposed to sandwich a portion of the semiconductor substrate in a first direction along the main surface so as to define a first active region; and
a first transistor formed in the first active region in plan view,
wherein the first transistor comprises:
a first gate dielectric film formed on the main surface of the semiconductor substrate;
a first gate electrode formed on the first gate dielectric film; and
a first semiconductor region and a second semiconductor region each formed in the semiconductor substrate, the first semiconductor region and the second semiconductor region being located on both sides of the first gate electrode in a second direction perpendicular to the first direction,
wherein the first gate dielectric film comprises in the first direction:
a first portion disposed spaced apart from the first element isolation film and the second element isolation film;
a second portion disposed between the first portion and the first element isolation film; and
a third portion disposed between the first portion and the second element isolation film,
wherein the second portion of the first gate dielectric film reaches the first element isolation film,
wherein the third portion of the first gate dielectric film reaches the second element isolation film,
wherein the first portion of the first gate dielectric film has a first thickness,
wherein each of the second portion and the third portion of the first gate dielectric film has a second thickness, and
wherein the second thickness is greater than the first thickness.

2. The semiconductor device according to claim 1,
wherein the first portion of the first gate dielectric film is a region where a filament is formed.

3. The semiconductor device according to claim 1,
wherein in the first direction, a width of each of the second portion and the third portion is 50 nm or more.

4. The semiconductor device according to claim 1,
wherein the first portion of the first gate dielectric film is formed of a first dielectric film having the first thickness, and
wherein each of the second portion and the third portion of the first gate dielectric film is formed of a laminated film including the first dielectric film and a second dielectric film having a third thickness greater than the first thickness.

5. The semiconductor device according to claim 4,
wherein the second dielectric film of the second portion extends on the first element isolation film, and
wherein the second dielectric film of the third portion extends on the second element isolation film.

6. The semiconductor device according to claim 4, comprising:
a second active region defined at the main surface of the semiconductor substrate; and
a second transistor formed in the second active region in plan view,
wherein the second transistor comprises:
a second gate dielectric film formed on the main surface of the semiconductor substrate;
a second gate electrode formed on the second gate dielectric film; and
a third semiconductor region and a fourth semiconductor region each formed in the semiconductor substrate, the third semiconductor region and the fourth semiconductor region being located on both sides of the second gate electrode,
wherein a fourth thickness of the second gate dielectric film in the second active region is equal to the second thickness of each of the second portion and the third portion of the first gate dielectric film in the first active region.

7. The semiconductor device according to claim 6, comprising:
a third active region defined at the main surface of the semiconductor substrate; and
a third transistor formed in the third active region in plan view,
wherein the third transistor comprises:
a third gate dielectric film formed on the main surface of the semiconductor substrate;
a third gate electrode formed on the third gate dielectric film; and
a fifth semiconductor region and a sixth semiconductor region each formed in the semiconductor substrate, the fifth semiconductor region and the sixth semiconductor region being located on both sides of the third gate electrode,
wherein a fifth thickness of the third gate dielectric film in the third active region is equal to the first thickness of the first portion of the first gate dielectric film in the first active region.

8. The semiconductor device according to claim 7,
wherein a first length of the second gate electrode in a direction connecting the third semiconductor region and the fourth semiconductor region of the second transistor is greater than a second length of the third gate electrode in a direction connecting the fifth semiconductor region and the sixth semiconductor region of the third transistor.

9. The semiconductor device according to claim 8,
wherein a first power-supply voltage applied to the second gate electrode of the second transistor is higher than a second power-supply voltage applied to the third gate electrode of the third transistor.

10. The semiconductor device according to claim 1,
wherein each of the first element isolation film and the second element isolation film has a shallow portion and a deep portion deeper than the shallow portion,
wherein the shallow portion of the first element isolation film is disposed between the first active region and the deep portion of the first element isolation film,
wherein the shallow portion of the second element isolation film is disposed between the first active region and the deep portion of the second element isolation film,
wherein the second portion of the first gate dielectric film reaches the shallow portion of the first element isolation film, and
wherein the third portion of the first gate dielectric film reaches the shallow portion of the second element isolation film.

11. A method of manufacturing a semiconductor device, the method comprising:
(a) preparing a semiconductor substrate having a main surface;
(b) forming a first element isolation film and a second element isolation film each extending from the main surface toward an inside of the semiconductor substrate, the first element isolation film and the second element isolation film being disposed to sandwich a portion of the semiconductor substrate in a first direction along the main surface so as to define a first active region;
(c) forming a first gate dielectric film on the main surface of the semiconductor substrate in the first active region;
(d) forming a first gate electrode on the first gate dielectric film; and
(e) forming a first semiconductor region and a second semiconductor region in the semiconductor substrate, the first semiconductor region and the second semiconductor region being located on both sides of the first gate electrode in a second direction perpendicular to the first direction,
wherein the first gate dielectric film comprises in the first direction:
a first portion disposed spaced apart from the first element isolation film and the second element isolation film;
a second portion disposed between the first portion and the first element isolation film; and
a third portion disposed between the first portion and the second element isolation film,
wherein the second portion of the first gate dielectric film reaches the first element isolation film,
wherein the third portion of the first gate dielectric film reaches the second element isolation film,
wherein the first portion of the first gate dielectric film has a first thickness,
wherein each of the second portion and the third portion of the first gate dielectric film has a second thickness, and
wherein the second thickness is greater than the first thickness.

12. The method according to claim 11,
wherein the first portion of the first gate dielectric film is a region where a filament is formed.

13. The method according to claim 11,
wherein in the first direction, a width of each of the second portion and the third portion is 50 nm or more.

14. The method according to claim 11,
wherein the (c) comprises:
(c1) forming a first dielectric film on the main surface of the semiconductor substrate in the first active region;
(c2) removing a portion of the first dielectric film spaced apart from the first element isolation film and the second element isolation film in the first direction to form an opening portion exposing the main surface in the first active region; and
(c3) forming a second dielectric film on the main surface exposed from the opening portion in the first active region,
wherein the first portion of the first gate dielectric film is formed of the second dielectric film, and
wherein a third thickness of the first dielectric film is greater than a fourth thickness of the second dielectric film.

15. The method according to claim 14,
wherein in the (c3), between the opening portion and the first element isolation film and between the opening portion and the second element isolation film, the second dielectric film is formed between the main surface of the semiconductor substrate and the first dielectric film,
wherein each of the second portion and the third portion is formed of a laminated film including the first dielectric film and the second dielectric film.

16. The method according to claim 14,
wherein the (b) comprises forming a third element isolation film and a fourth element isolation film each extending toward an inside of the semiconductor substrate, the third element isolation film and the fourth element isolation film being disposed to sandwich a second region of the main surface of the semiconductor substrate in the first direction along the main surface so as to define a second active region,
wherein the (c) comprises forming a second gate dielectric film on the main surface of the semiconductor substrate in the second active region,
wherein the (d) comprises forming a second gate electrode on the second gate dielectric film in the second active region,
wherein the (c1) comprises forming the first dielectric film on the main surface of the semiconductor substrate in the second active region,
wherein the (c3) comprises forming the second dielectric film between the main surface of the semiconductor substrate and the first dielectric film in the second active region, and
wherein the second gate dielectric film is formed of a laminated film including the first dielectric film and the second dielectric film in the second active region.

17. The method according to claim 16,
wherein the (b) comprises forming a fifth element isolation film and a sixth element isolation film each extending toward an inside of the semiconductor substrate, the fifth element isolation film and the sixth element isolation film being disposed to sandwich a third region of the main surface of the semiconductor substrate in the first direction along the main surface so as to define a third active region,
wherein the (c) comprises forming a third gate dielectric film on the main surface of the semiconductor substrate in the third active region,
wherein the (d) comprises forming a third gate electrode on the third gate dielectric film in the third active region,
wherein the (c1) comprises forming the first dielectric film on the main surface of the semiconductor substrate in the third active region,
wherein the (c2) comprises removing the first dielectric film in the third active region,
wherein the (c3) comprises forming the second dielectric film on the main surface of the semiconductor substrate in the third active region, and
wherein the third gate dielectric film is formed of the second dielectric film in the third active region.

18. The method according to claim 11,
wherein the (b) comprises:
(b1) forming a third dielectric film on the main surface of the semiconductor substrate, the third dielectric film covering the first region and exposing a region where the first element isolation film and the second element isolation film are formed;
(b2) forming a first trench and a second trench in the semiconductor substrate in the region where the first element isolation film and the second element isolation film are formed;
(b3) forming a fourth dielectric film on the third dielectric film so as to fill the first trench and the second trench;
(b4) performing a polishing process to the fourth dielectric film to selectively form the first element isolation film and the second element isolation film in the first trench and the second trench; and
(b5) removing the third dielectric film.

19. The method according to claim 11,
wherein the (b) comprises:
(b1) forming a polycrystalline silicon film and a third dielectric film in this order on the main surface of the semiconductor substrate, the polycrystalline silicon film and the third dielectric film each covering the first region and exposing a region where the first element isolation film and the second element isolation film are formed;
(b2) forming a first recess and a second recess at the main surface of the semiconductor substrate exposed from the polycrystalline silicon film and the third dielectric film;
(b3) forming sidewall dielectric films on sidewalls of the polycrystalline silicon film and the third dielectric film, on the first recess and on the second recess;
(b4) forming a first trench and a second trench in the semiconductor substrate and at a bottom surface of the first recess and a bottom surface of the second recess exposed from the third dielectric film and the sidewall dielectric films;
(b5) after removing the sidewall dielectric films, forming a fourth dielectric film on the third dielectric film so as to fill the first recess, the second recess, the first trench and the second trench;
(b6) performing a polishing process to the fourth dielectric film to form the element isolation film in the first recess and in the first trench and to form the second element isolation film in the second recess and in the second trench; and
(b7) removing the third dielectric film and the polycrystalline silicon film.

20. The method according to claim 19,
wherein the second portion of the first gate dielectric film reaches the first element isolation film formed in the first recess, and
wherein the third portion of the first gate dielectric film reaches the second element isolation film formed in the second recess.
